(19) United States
(12) Patent Application Publication
(10) Pub. No.: US 2024/0299957 A1
(43) Pub. Date: Sep. 12, 2024

(54) SUBSTRATE TREATMENT APPARATUS

(71) Applicant: JUSUNG ENGINEERING CO., LTD., Gyeonggi-do (KR)

(72) Inventors: Ji Hun LEE, Gwangju-si, Gyeonggi-do (KR); Ji Won LEE, Gwangju-si, Gyeonggi-do (KR)

(21) Appl. No.: 18/274,458

(22) PCT Filed: Jan. 10, 2022
(86) PCT No.: PCT/KR2022/000367

§ 371 Date: Jul. 26, 2023

(30) Foreign Application Priority Data
Jan. 29, 2021 (KR) 10-2021-0012764

(51) Int. Cl. B05B 1/14; B05B 1/00; B05B 13/02

(52) U.S. Cl. CPC B05B 1/14; B05B 1/005; B05B 13/02

(57) ABSTRACT

The present inventive concept relates to a substrate treatment apparatus comprising: a chamber; a substrate support portion which supports at least one substrate in the chamber; a first spray portion which sprays a first gas toward the substrate support portion from the upper side of the substrate support portion; a second spray portion which sprays a second gas toward the substrate support portion from the upper side of the first spray portion; and a buffer portion formed between the first spray portion and the second spray portion, wherein the first spray portion includes a plurality of first spray holes and the second spray portion includes a first supply hole which supplies the first gas to the buffer portion and a second spray hole which passes through the buffer portion. The center of an injection port and the center of a discharge port of the first supply hole are spaced apart from each other in the vertical direction, and the discharge port is formed toward a space among the first spray holes.

### TECHNICAL FIELD

The present inventive concept relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Such a processing process is performed on a substrate by a substrate processing apparatus.

A substrate processing apparatus of the related art includes a substrate supporting unit which supports a substrate and a gas injection unit which injects gas toward the substrate supporting unit. The substrate processing apparatus of the related art performs a processing process on the substrate by using first and second gases which differ. The first gas and the second gas are supplied into the gas injection unit and move along individual gas flow paths formed in the gas injection unit, and then, are injected from the gas injection unit.

The gas injection unit includes a first injection unit which injects a gas toward the substrate supporting unit and a second injection unit which is disposed on the first injection unit. The first injection unit includes a plurality of first supply holes and a plurality of second supply holes. The second injection unit includes a plurality of first injection holes and a plurality of second injection holes. The first supply holes and the first injection holes correspond to the first gas flow path. The second supply holes and the second injection holes correspond to the second gas flow path.

Here, the first gas is supplied to a first injection hole, disposed vertically under the first supply hole among the first injection holes, at a higher flow rate than the first gas supplied to the other first injection holes and is supplied at stronger pressure than the first gas supplied to the other first injection holes. Therefore, in the substrate processing apparatus of the related art, a deviation occurs in an injection flow rate and an injection pressure of the first gas between the first injection holes, and due to this, the uniformity of a processing process performed on a substrate is reduced.

### DISCLOSURE

### Technical Problem

The present inventive concept is devised to solve the above-described problem and is for providing a substrate processing apparatus which may decrease a deviation in an injection pressure and a flow rate of a gas.

### Technical Solution

To accomplish the above-described objects, the present inventive concept may include the following elements.

A substrate processing apparatus according to the present inventive concept may include: a chamber; a substrate supporting unit supporting at least one substrate, in the chamber; a first injection unit injecting a first gas toward the substrate supporting unit, over the substrate supporting unit; a second injection unit injecting a second gas toward the substrate supporting unit, over the first injection unit; and a buffer unit formed between the first injection unit and the second injection unit. The first injection unit may include a plurality of first injection holes. The second injection unit may include a first supply hole supplying the first gas to the buffer unit and a second injection hole formed to pass through the buffer unit. Centers of an inlet and an outlet of the first supply hole may be disposed apart from each other with respect to a vertical direction, and the outlet may be formed to face a space between the first injection holes.

### Advantageous Effect

According to the present inventive concept, the following effects may be realized.

The present inventive concept may induce a first gas so that the first gas flows in a buffer unit to diffuse, thereby enhancing the uniformity of pressure and a flow rate at which the first gas is supplied to first injection holes. Accordingly, the present inventive concept may decrease a deviation which occurs in an injection flow rate and an injection pressure of the first gas injected through the first injection holes, and thus, may contribute to enhance the uniformity of a processing process performed on a substrate.

### DESCRIPTION OF DRAWINGS

FIG. 1 is a schematic block diagram of a substrate processing apparatus according to the present inventive concept.

FIGS. 2 to 4 are schematic side cross-sectional views of a gas injection unit in a substrate processing apparatus according to the present inventive concept.

FIG. 5 is a schematic plan view of a second injection unit in a substrate processing apparatus according to the present inventive concept.

FIGS. 6 to 9 are schematic enlarged views of a region A of FIG. 5.

FIG. 10 is a schematic side cross-sectional view of an embodiment where a substrate processing apparatus according to the present inventive concept includes an electrode unit.

### MODE FOR INVENTION

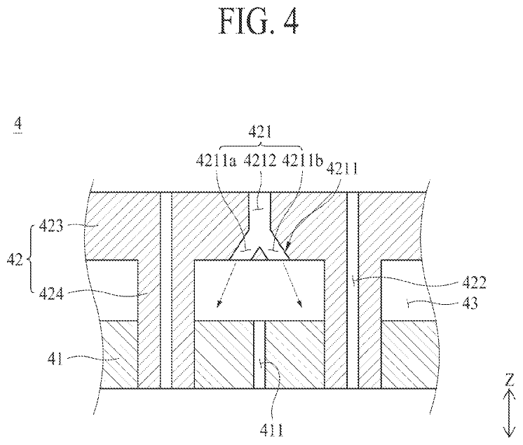

Hereinafter, an embodiment of a substrate processing apparatus according to the present inventive concept will be described in detail with reference to the accompanying drawings. In FIG. 4, a first supply hole and a second injection hole formed in a second injection unit are omitted.

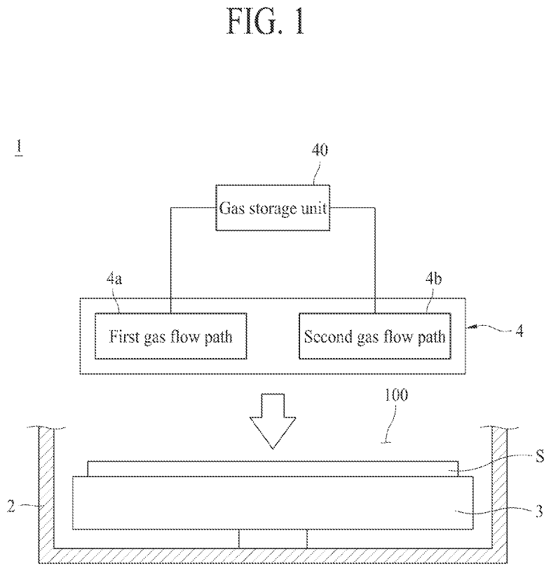

Referring to FIG. 1, a substrate processing apparatus 1 according to the present inventive concept performs a processing process on a substrate S. The substrate S may be a silicon substrate, a glass substrate, a metal substrate, or the like. The substrate processing apparatus 1 according to the present inventive concept may perform a deposition process of depositing a thin film on the substrate S, an etching process of removing a portion of the thin film deposited on the substrate S, etc. Hereinafter, an embodiment where the substrate processing apparatus 1 according to the present inventive concept performs the deposition process will be described mainly, and based thereon, it is obvious to those skilled in the art that an embodiment is devised where the substrate processing apparatus 1 according to the present inventive concept performs another processing process such as the etching process.

The substrate processing apparatus 1 according to the present inventive concept may include a chamber 2, a substrate supporting unit 3, and a gas injection unit 4.

### <Chamber>

Referring to FIG. 1, the chamber 2 provides a processing space 100. A processing process such as a deposition process and an etching process on the substrate S may be performed in the processing space 100. The processing space 100 may be disposed in the chamber 2. An exhaust port (not shown) which exhausts a gas from the processing space 100 may be coupled to the chamber 2. The substrate supporting unit 3 and the gas injection unit 4 may be disposed in the chamber 2.

### <Substrate Supporting Unit>

Referring to FIG. 1, the substrate supporting unit 3 supports the substrate S. The substrate supporting unit 3 may support one substrate S, or may support a plurality of substrates S. In a case where the plurality of substrates S are supported by the substrate supporting unit 3, the processing process may be performed on the plurality of substrates S at a time. The substrate supporting unit 3 may be coupled to the chamber 2. The substrate supporting unit 3 may be disposed in the chamber 2.

### <Gas Injection Unit>

Referring to FIG. 1, the gas injection unit 4 injects a gas toward the substrate supporting unit 3. The gas injection unit 4 may be connected to a gas storage unit 40. In this case, the gas injection unit 4 may inject a gas, supplied from the gas storage unit 40, toward the substrate supporting unit 3. The gas injection unit 4 may be disposed to be opposite to the substrate supporting unit 3. The gas injection unit 4 may be disposed over the substrate supporting unit 3 with respect to a vertical direction (a Z-axis direction). The vertical direction (the Z-axis direction) is an axis direction parallel to a direction in which the gas injection unit 4 is apart from the substrate supporting unit 3. The processing space 100 may be disposed between the gas injection unit 4 and the substrate supporting unit 3. The gas injection unit 4 may be coupled to a lid (not shown). The lid may be coupled to the chamber 2 to cover an upper portion of the chamber 2.

The gas injection unit 4 may include a first gas flow path 4a and a second gas flow path 4b.

The first gas flow path 4a is for injecting a first gas. The first gas flow path 4a may be connected to the gas storage unit 40 at one side thereof through a pipe, a hose, or the like. The other side of the first gas flow path 4a may communicate with the processing space 100. Therefore, the first gas supplied from the gas storage unit 40 may flow along the first gas flow path 4a, and then, may be injected into the processing space 100 through the first gas flow path 4a. The first gas flow path 4a may function as a flow path for enabling the first gas to flow and may function as an inlet for injecting the first gas.

The second gas flow path 4b is for injecting a second gas. The second gas and the first gas may be different gases. For example, when the first gas is a reactant gas, the second gas may be a source gas. The second gas flow path 4b may be connected to the gas storage unit 40 at one side thereof through a pipe, a hose, or the like. The other side of the second gas flow path 4b may communicate with the processing space 100. Therefore, the second gas supplied from the gas storage unit 40 may flow along the second gas flow path 4b, and then, may be injected into the processing space 100 through the second gas flow path 4b. The second gas flow path 4b may function as a flow path for enabling the second gas to flow and may function as an inlet for injecting the second gas.

The second gas flow path 4b and the first gas flow path 4a may be disposed to be spatially apart from each other. Therefore, the second gas supplied from the gas storage unit 40 to the second gas flow path 4b may be injected into the processing space 100 without passing through the first gas flow path 4a. The first gas supplied from the gas storage unit 40 to the first gas flow path 4a may be injected into the processing space 100 without passing through the second gas flow path 4b. The second gas flow path 4b and the first gas flow path 4a may inject a gas toward different portions in the processing space 100.

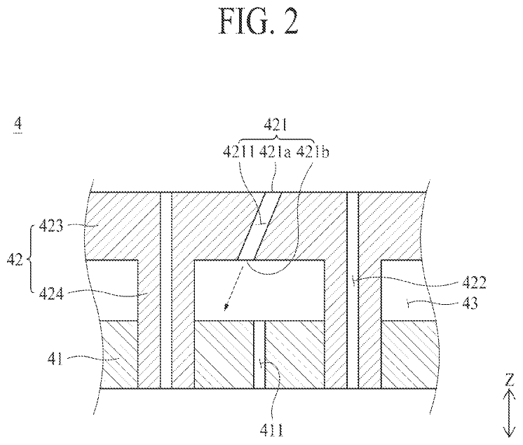

Referring to FIGS. 1 and 2, the gas injection unit 4 may include a first injection unit 41 and a second injection unit 42.

The first injection unit 41 injects the first gas toward the substrate supporting unit 3, over the substrate supporting unit 3. The first injection unit 41 may be disposed under the second injection unit 42. The first injection unit 41 may include a plurality of first injection holes 411.

The first injection holes 411 may be formed to pass through the first injection unit 41. The first injection holes 411 may function as a flow path for enabling the first gas to flow and may function as an inlet for injecting the second gas. In this case, the first injection holes 411 may be provided in the first gas flow path 4a. The first gas may flow through the first injection holes 411 and may be injected toward the substrate S. The first injection holes 411 may be formed to pass through the first injection unit 41 at positions apart from one another.

The second injection unit 42 injects the second gas toward the substrate supporting unit 3, over the first injection unit 41. The second injection unit 42 may be disposed over the first injection unit 41. The first injection unit 41 may include a plurality of first injection holes 411. The second injection unit 42 may supply the first gas to a buffer unit 43. The buffer unit 43 is provided between the first injection unit 41 and the second injection unit 42. The first gas supplied from the second injection unit 42 to the buffer unit 43 may be injected toward the substrate supporting unit 3 through the first injection holes 411.

The second injection unit 42 may include a first supply hole 421 and a second injection hole 422.

The first supply hole 421 supplies the first gas to the buffer unit 43. The first supply hole 421 may be formed to pass through the second injection unit 42. The first supply hole 421 may function as a flow path for enabling the first gas to flow. The first supply hole 421 may be provided in the first gas flow path 4a. The first supply hole 421, the buffer unit 43, and the first injection holes 411 may be provided in the first gas flow path 4a. The second injection unit 42 may include a plurality of first supply holes 421. The first supply holes 421 may be formed to pass through the second injection unit 42 at positions apart from one another. The first supply holes 421 may be connected to the gas storage unit 40. The second injection unit 42 may include a plurality of first supply holes 421. The first supply holes 421 may be formed to pass through the second injection unit 42 at positions apart from one another.

The second injection hole 422 injects the second gas. The second injection hole 422 may be formed to pass through the buffer unit 43. The second injection hole 422 may function as a flow path for enabling the second gas to flow and may function as an injection port for injecting the second gas. In this case, the second injection hole 422 may be provided in the second gas flow path 4b.

The second injection hole 422 may be formed to pass through all of an injection body 423 and a connection unit 424 which are included in the second injection unit 42. The injection body 423 is disposed upward apart from the first injection unit 41. The first supply hole 421 may be formed in the injection body 423. The connection unit 424 protrudes from the injection body 423. One side of the connection unit 424 may protrude from a bottom surface of the injection body 423, and the other side thereof may be inserted into the first injection unit 41. A region between the other side of the connection unit 424 and the first injection unit 41 may be sealed. The one side of the connection unit 424 and the other side of the connection unit 424 may be disposed in the buffer unit 43. Therefore, the buffer unit 43 may be spatially divided into an inner space of the connection unit 424 and an outer space of the connection unit 424. Accordingly, the second injection unit 42 may divide the buffer unit 43 by using the connection unit 424 so that the first gas flow path 4a is spatially apart from the second gas flow path 4b.

The first gas flow path 4a may be implemented by using the outer space of the connection unit 424 at the buffer unit 43. In this case, the buffer unit 43 provided in the first gas flow path 4a may have a buffer function for diffusing the first gas. The first gas may sequentially pass through the first supply hole 421, the buffer unit 43, and the first injection hole 411, and thus, may be injected toward the substrate supporting unit 3.

The second gas flow path 4b may be implemented by using the inner space of the connection unit 424 at the buffer unit 43. In this case, the inner space of the connection unit 424 may correspond to a portion of the second injection hole 422. The second gas may pass through the second injection hole 422, and thus, may be injected toward the substrate supporting unit 3.

The second injection unit 42 may include a plurality of second injection holes 422. The second injection holes 422 may be formed to pass through the second injection unit 42 at positions apart from one another. In this case, the second injection unit 42 may include a plurality of connection units 424. The second injection holes 422 may be formed to respectively pass through the connection units 424.

Here, in a case where the first supply hole 421 and the first injection holes 411 are formed to extend in parallel with the vertical direction (the Z direction), the first gas may be supplied through a first injection hole 411, disposed to face the first supply hole 421, at a higher flow rate and stronger pressure than the first gas supplied to the other first injection holes 411. This is because the first gas supplied from the first supply hole 421 is injected toward the first injection hole 411 disposed to face the first supply hole 421. Therefore, as a deviation occurs in an injection flow rate and an injection pressure of the first gas between the first injection holes 411, the uniformity of a processing process on the substrate S may be reduced. To solve such a problem, in the substrate processing apparatus 1 according to the present inventive concept, the gas injection unit 4 may be implemented as follows.

As illustrated in FIG. 2, the first supply hole 421 may include an inlet 421a and an outlet 421b. The inlet 421a may pass through a top surface of the second injection unit 42. The outlet 421b may pass through a bottom surface of the second injection unit 42. A center of the inlet 421a and a center of the outlet 421b may be disposed apart from each other with respect to the vertical direction (the Z direction). That is, the center of the inlet 421a and the center of the outlet 421b may be disposed to be staggered. Accordingly, the first gas injected from the outlet 421b may be injected into a space between the first injection holes 411. In this case, the first supply hole 421 may inject the first gas toward a top surface of the first injection unit 41 disposed between the first injection holes 411.

Therefore, the substrate processing apparatus 1 according to the present inventive concept may induce the first gas so that the first gas injected from the first supply hole 421 flows along the top surface of the first injection unit 41 to diffuse in the buffer unit 43, thereby enhancing the uniformity of pressure and a flow rate at which the first gas is supplied to the first injection holes 411. Accordingly, the substrate processing apparatus 1 according to the present inventive concept may decrease a deviation which occurs in an injection flow rate and an injection pressure of the first gas injected through the first injection holes 411, and thus, may contribute to enhance the uniformity of the processing process performed on the substrate S.

When the center of the inlet 421a and the center of the outlet 421b are disposed to be staggered, the connection units 424 may be disposed at positions apart from a flow path (illustrated as a dotted-line arrow in FIG. 2) of the first gas injected from the first supply hole 421. Therefore, the first gas injected from the first supply hole 421 may be prevented from being stopped by an eddy which occurs when colliding with the connection units 424. Accordingly, the substrate processing apparatus 1 according to the present inventive concept may more increase the diffusion of the first gas injected from the first supply hole 421.

The first supply hole 421 may include a slope path 4211.

The slope path 4211 is disposed between the inlet 421a and the outlet 421b. The slope path 4211 may be formed diagonally between the inlet 421a and the outlet 421b. In this case, the slope path 4211 may be formed to be inclined in a direction distancing from the inlet 421a as the slope path 4211 extends downward. Based on the slope path 4211, the center of the inlet 421a and the center of the outlet 421b included in the first supply hole 421 may be disposed to be staggered. The slope path 4211 may be formed in an inclined shape at a certain angle with respect to the vertical direction (the Z-axis direction). The slope path 4211 may be connected to the outlet 421b. The first gas injected from the outlet 421b by the slope path 4211 may contact the top surface of the first injection unit 41 at an inclined angle with respect to a plane which is the top surface of the first injection unit 41. Accordingly, the substrate processing apparatus 1 according to the present inventive concept may induce the first gas to be smoothly diffused in the buffer unit 43, and thus, may more increase the diffusion of the first gas. The slope path 4211 may be connected to each of the outlet 421b and the inlet 421a.

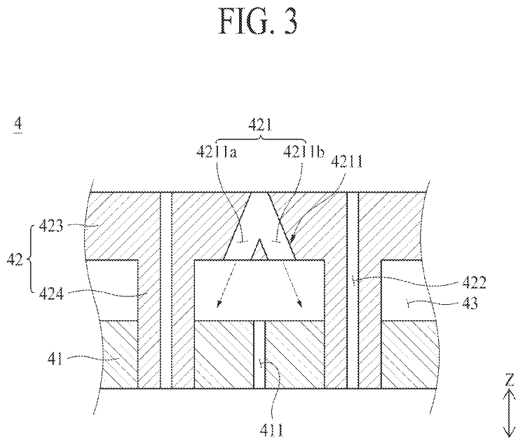

As illustrated in FIG. 3, the slope path 4211 of the first supply hole 421 may be formed in plurality. The slope paths 4211 may be formed to extend in different directions. Therefore, the substrate processing apparatus 1 according to the present inventive concept may inject the first gas in different directions by using the slope paths 4211, and thus, may more diffuse the first gas. Accordingly, the substrate processing apparatus 1 according to the present inventive concept may more increase the diffusion of the first gas, and thus, may more enhance the uniformity of a processing process using the first gas. For example, the first supply hole 421 may include a first slope path 4211a and a second slope path 4211b. The first slope path 4211a and the second slope path 4211b may be formed to be inclined in different directions. In FIG. 3, the first supply hole 421 is illustrated as including two slope paths 4211, but is not limited thereto and the first supply hole 421 may include three or more slope paths 4211.

As illustrated in FIG. 4, the first supply hole 421 may include a vertical path 4212. The vertical path 4212 extends vertically in the vertical direction (the Z-axis direction) from the inlet 421a (illustrated in FIG. 2). The vertical path 4212 may be connected to the inlet 421a (illustrated in FIG. 2). In this case, the slope path 4211 may be connected to each of the vertical path 4212 and the outlet 421b (illustrated in FIG. 2). The vertical path 4212 may be formed to rectilinearly extend downward with respect to a center of the inlet 421a (illustrated in FIG. 2). That is, the vertical paths 4212 may be formed in parallel with the vertical direction (the Z-axis direction). In this case, the slope path 4211 may be formed to be inclined in a direction distancing from the vertical paths 4212 as the slope path 4211 extends downward from the vertical path 4212.

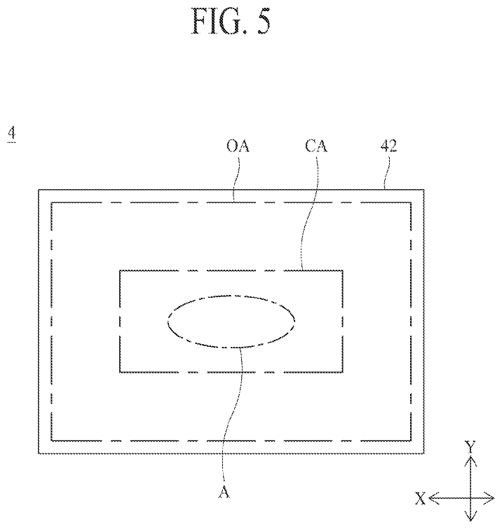

Referring to FIGS. 1 to 5, in the substrate processing apparatus 1 according to an embodiment of the present inventive concept, the first supply hole 421 may be disposed in a center region CA (illustrated in FIG. 5). The center region CA is a region having a certain area in a first-axis direction (an X-axis direction) and a second-axis direction (a Y-axis direction) from a center of the second injection unit 42. The first-axis direction (the X-axis direction) and the second-axis direction (the Y-axis direction) are axis directions which are vertical to the vertical direction (the Z-axis direction) and are perpendicular to each other. The center region CA may be disposed inward from an outer region OA (illustrated in FIG. 5). The outer region OA may be disposed to surround the center region CA at an outer portion of the center region CA. In this case, the second injection holes 422 may be disposed in all of the center region CA and the outer region OA. Although not shown, the first supply hole 421 may be disposed in the outer region OA.

Here, based on positions of the first supply holes 421 disposed in the second injection unit 42, a direction in which the slope paths 4211 are formed to extend may be determined. In this case, the slope paths 4211 may be formed to extend in a direction which enables the first gas, injected through the first supply holes 421, to be uniformly diffused in the buffer unit 43 (illustrated in FIG. 2).

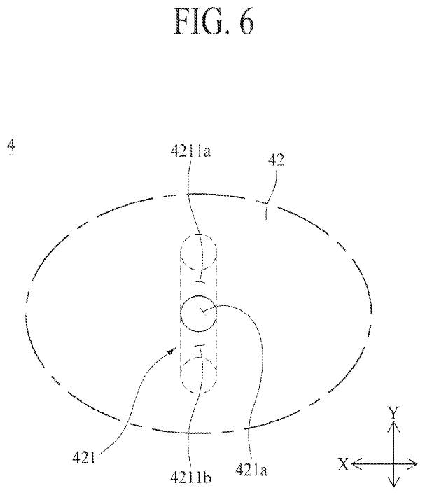

For example, as illustrated in FIG. 6, the slope paths 4211a and 4211b included in each of the first supply holes 421 may be formed to extend in directions opposite to each other. Accordingly, the first supply holes 421 may enhance the uniformity of a flow rate and a pressure of the first gas injected in directions opposite to each other by using the slope paths 4211a and 4211b.

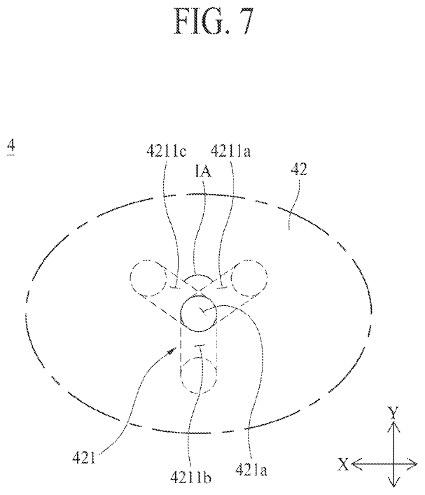

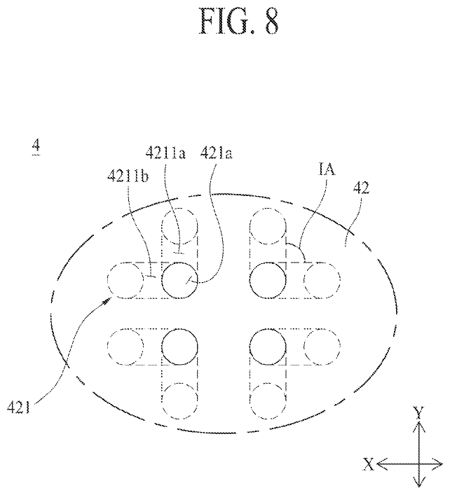

For example, as illustrated in FIG. 7, slope paths 4211a, 4211b, and 4211c included in each of the first supply holes 421 may be formed to extend in a direction corresponding to an included angle IA of the same angle. For example, the slope paths 4211a, 4211b, and 4211c may be formed to extend in a direction corresponding to the included angle IA of 120 degrees. Therefore, each of the first supply holes 421 may enhance the uniformity of a flow rate and a pressure of the first gas injected in different directions. In FIG. 7, an embodiment is illustrated where three slope paths 4211a, 4211b, and 4211c are formed to extend in a direction corresponding to an included angle IA of the same angle, but is not limited thereto and an embodiment may be implemented where two or four or more slope paths 4211 (illustrated in FIG. 4) extend in a direction corresponding to an included angle IA of the same angle. As illustrated in FIG. 8, the slope paths 4211a and 4211b may be formed to extend in a direction corresponding to the included angle IA of 90 degrees. In this case, the slope paths 4211a and 4211b of the first supply hole 421 may be formed to extend in directions perpendicular to each other.

For example, as illustrated in FIG. 8, the slope paths 4211a and 4211b included in each of the first supply holes 421 may be formed to extend in a different direction except a direction facing an adjacent first supply hole 421. In this case, the slope path 4211 (illustrated in FIG. 4) of the first supply hole 421 and the slope path 4211 (illustrated in FIG. 4) of an adjacent first supply hole 421 may be formed to extend in different directions. Therefore, the first supply holes 421 may inject the first gas in different directions by using the slope paths 4211a and 4211b. Accordingly, the substrate processing apparatus 1 according to an embodiment of the present inventive concept may more diffuse the first gas to the outside of a region where the first supply holes 421 are disposed, and thus, may enhance the uniformity of a flow rate and a pressure of the first gas.

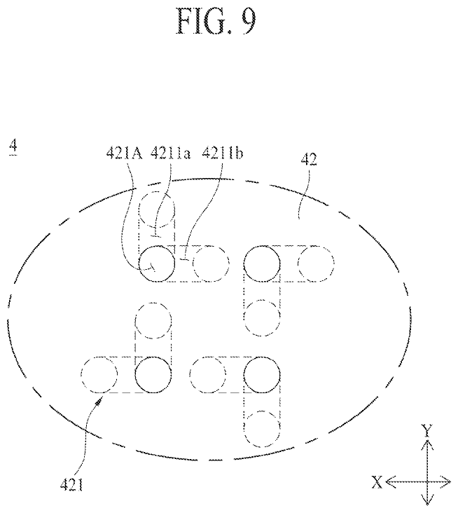

For example, as illustrated in FIG. 9, the first slope path 4211a of the slope paths 4211 included in each of the first supply holes 421 may be formed to extend in a direction facing an adjacent first supply hole 421, and the second slope path 4211b may be formed to extend in a different direction except a direction facing an adjacent first supply hole 421. Accordingly, the substrate processing apparatus 1 according to an embodiment of the present inventive concept may be implemented to more diffuse the first gas to the outside of a region where the first supply holes 421 are disposed, and moreover, to more diffuse the first gas in the region where the first supply holes 421 are disposed. In this case, the slope path 4211 (illustrated in FIG. 4) of the first supply hole 421 may be formed to extend in a direction which differs from at least one of the slope paths 4211 (illustrated in FIG. 4) of an adjacent first supply hole 421.

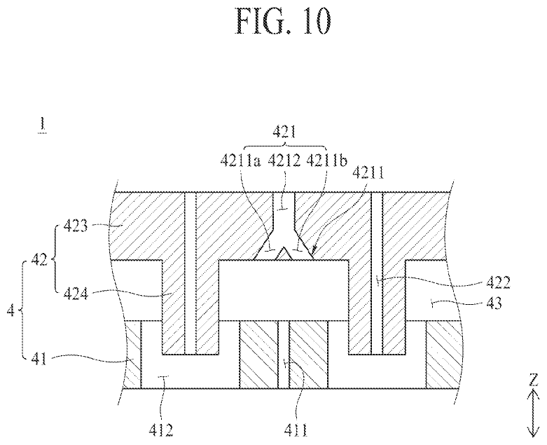

Referring to FIG. 10, in the substrate processing apparatus 1 according to an embodiment of the present inventive concept, the first injection unit 41 or the second injection unit 42 may be implemented to be connected to a radio frequency (RF) power source (not shown). In this case, when the first injection unit 41 is grounded and an RF power is applied to the second injection unit 42, plasma may be generated. Accordingly, the gas injection unit 4 may activate at least one of the first gas and the second gas by using plasma and may inject the activated gas into the processing space 100. The second injection unit 42 may be grounded, and the RF power may be applied to the first injection unit 41.

The first injection unit 41 may include a plurality of openings 412. The openings 412 may be formed to pass through the first injection unit 41 at different positions. In this case, a portion of the first injection unit 41 may be inserted into each of the openings 412. The connection units 424 of the first injection unit 41 may be respectively inserted into the openings 412. In FIG. 10, it is illustrated that bottom surfaces of the connection units 424 are disposed higher than a bottom surface of the first injection unit 41, but the present inventive concept is not limited thereto and the bottom surfaces of the connection units 424 and the bottom surface of the first injection unit 41 may be implemented at the same height. The bottom surfaces of the connection units 424 may be disposed lower than the bottom surface of the first injection unit 41. In this case, the connection units 424 may protrude downward with respect to the first injection unit 41.

In a case where the openings 412 are provided, the first gas may be supplied to the buffer unit 43 through the first supply hole 421, and then, may be diffused in the buffer unit 43 and may be injected toward the substrate supporting unit 3 through each of the first injection holes 411 and the openings 412.

The present inventive concept described above are not limited to the above-described embodiments and the accompanying drawings and those skilled in the art will clearly appreciate that various modifications, deformations, and substitutions are possible without departing from the scope and spirit of the invention.

1. A substrate processing apparatus comprising:
a chamber;
a substrate supporting unit supporting at least one substrate, in the chamber;
a first injection unit injecting a first gas toward the substrate supporting unit, over the substrate supporting unit;
a second injection unit injecting a second gas toward the substrate supporting unit, over the first injection unit; and
a buffer unit formed between the first injection unit and the second injection unit,
wherein the first injection unit comprises a plurality of first injection holes,
the second injection unit comprises a first supply hole supplying the first gas to the buffer unit and a second injection hole formed to pass through the buffer unit,
centers of an inlet and an outlet of the first supply hole are disposed apart from each other with respect to a vertical direction, and
the outlet is formed to face a space between the first injection holes.

2. The substrate processing apparatus of claim 1, wherein the first supply hole comprises a slope path disposed between the inlet and the outlet, and
the slope path is formed diagonally between the inlet and the outlet.

3. The substrate processing apparatus of claim 2, wherein the first supply hole further comprises a vertical path extending vertically in the vertical direction from the inlet.

4. The substrate processing apparatus of claim 2, wherein a slope path of the first supply hole is formed in plurality, and
the slope paths are formed to extend in different directions.

5. The substrate processing apparatus of claim 4, wherein the slope paths of the first supply hole are formed to extend in directions opposite to each other.

6. The substrate processing apparatus of claim 4, wherein the slope paths of the first supply hole are formed to extend in directions vertical to each other.

7. The substrate processing apparatus of claim 4, wherein the first supply hole is formed in plurality, and
one of the slope paths of one of the first supply holes is formed to extend in a direction which differs from at least one of the slope paths of another one adjacent first supply hole.

8. The substrate processing apparatus of claim 2, wherein the first supply hole is formed in plurality, and
the slope path of one of the first supply holes and the slope path of another one adjacent first supply hole are formed to extend in different directions.

9. The substrate processing apparatus of claim 1, wherein the first injection unit or the second injection unit is connected to a radio frequency (RF) power source.

10. The substrate processing apparatus of claim 3, wherein a slope path of the first supply hole is formed in plurality, and
the slope paths are formed to extend in different directions.

11. The substrate processing apparatus of claim 3, wherein the first supply hole is formed in plurality, and
the slope path of one of the first supply holes and the slope path of another one adjacent first supply hole are formed to extend in different directions.
